(19) United States
(12) Patent Application Publication
(10) Pub. No.: US 2004/0245652 A1
(43) Pub. Date: Dec. 9, 2004

(54) Semiconductor device, electronic device, electronic appliance, and method of manufacturing a semiconductor device

(75) Inventor: Yoshiharu Ogata, Sakata-shi (JP)

Correspondence Address: HOGAN & HARTSON L.L.P., 500 S. GRAND AVENUE, SUITE 1900, LOS ANGELES, CA, 90071-2611, US

(73) Assignee: SEIKO EPSON CORPORATION

(21) Appl. No.: 10/812,346

(22) Filed: Mar. 29, 2004

(30) Foreign Application Priority Data
Mar. 31, 2003 (JP) 2003-095975

(51) Int. Cl. H01L 23/48

(52) U.S. Cl. 257/777

(57) ABSTRACT

A semiconductor device includes a substrate provided with terminals for connecting conductive wires, a first semiconductor chip mounted face-up on the substrate and electrically connected to the terminals provided on the substrate by the conductive wires and a second semiconductor chip having a projecting part formed on a rear surface thereof and attached onto the first semiconductor chip via the projecting part.

### BACKGROUND OF THE INVENTION

1. Field of the Invention

The present invention relates to a semiconductor device, an electronic device, an electronic appliance, and a method of manufacturing a semiconductor device, and is especially suited to a stacked structure of semiconductor chips.

2. Description of the Related Art

There exists a method for connecting stacked semiconductor chips by wire bonding to realize a three-dimensionally mounted structure of semiconductor chips in a conventional semiconductor device. FIG. 11 is a schematic cross-sectional view showing the structure of the conventional semiconductor device.

In FIG. 11, lands 102 that connect conductive wires 104d, 105d are provided on a front surface of a carrier substrate 101, and projecting electrodes 103 are provided on a rear surface of the carrier substrate 101. Semiconductor chips 104a, 105a are respectively provided with electrode pads 104b, 105b that connect conductive wires 104d, 105c. The semiconductor chip 104a is mounted face-up on the carrier substrate 101 via an adhesive layer 104c. In addition, the semiconductor chip 105a is mounted face-up via a mirror chip 106a that has adhesive layers 106b, 106c provided on both surfaces. Here, the mirror chip 106a is disposed between the semiconductor chips 104a, 105a so as to avoid the electrode pads 104b provided on the semiconductor chip 104a.

The semiconductor chip 104a mounted on the carrier substrate 101 is electrically connected via the conductive wires 104d to the lands 102 on the carrier substrate 101, and the semiconductor chip 104b stacked on top of the semiconductor chip 104a via the mirror chip 106a is electrically connected via the conductive wires 105d to the lands 102 on the carrier substrate 101. The semiconductor chips 104a, 105a to which the conductive wires 104d, 105d are respectively connected are sealed by sealing resin 107.

Here, by disposing the mirror chip 106a between the semiconductor chips 104a, 105a, it is possible to increase the gap between the semiconductor chips 104a, 105a. This means that the conductive wires 104d connected to the lower-level semiconductor chip 104a are prevented from contacting the upper-level semiconductor chip 105a, and it is possible to connect the lower-level semiconductor chip 104a by wire bonding even when semiconductor chips 104a, 105a of an equal size are stacked.

However, in the semiconductor device shown in FIG. 11, to connect the lower-level semiconductor chip 104a by wire bonding, it is necessary to dispose the mirror chip 106a between the semiconductor chips 104a, 105a, which increases the number of manufacturing processes and can lead to higher costs.

For this reason, it is an advantage of the present invention to provide a semiconductor device, an electronic device, an electronic appliance, and a method of manufacturing a semiconductor device where increases in the number of manufacturing processes are suppressed and it is possible to increase the gaps between stacked semiconductor chips.

### SUMMARY OF THE INVENTION

To solve the above problems, a semiconductor device according to an aspect of the present invention includes a substrate provided with terminals for connecting conductive wires, a first semiconductor chip that is mounted face-up on the substrate and is electrically connected to the terminals provided on the substrate by the conductive wires, and a second semiconductor chip that has a projecting part formed on a rear surface thereof and is attached onto the first semiconductor chip via the projecting part.

In this way, by stacking the second semiconductor chip on the first semiconductor chip, it is possible to fix the first semiconductor chip and the second semiconductor chip while maintaining a fixed gap between the first semiconductor chip and the second semiconductor chip. This means that while suppressing the increases in the number of manufacturing processes, it is possible to increase the gap between the first semiconductor chip and the second semiconductor chip, and it is possible to connect the first semiconductor chip by wire bonding even in the case where the first semiconductor chip and the second semiconductor chip are the same size.

A semiconductor device according to an aspect of the present invention further includes an insulating resin that attaches the second semiconductor chip onto the first semiconductor chip via the projecting part.

In this way, by stacking the second semiconductor chip on the first semiconductor chip via the insulating resin, it is possible to provide sufficient insulation between the first semiconductor chip and the second semiconductor chip, and while suppressing the increases in the number of manufacturing processes, it is possible to attach the second semiconductor chip onto the first semiconductor chip.

In a semiconductor device according to an aspect of the present invention, filler is mixed in with the insulating resin. By doing so, it is possible to reduce the hydrophilia of the insulating resin and to make the linear expansion coefficient of the insulating resin closer to that of the semiconductor chips, so that it is possible to ease the stress caused by the insulating resin and thereby improve the reliability of the semiconductor device.

In a semiconductor device according to an aspect of the present invention, the insulating resin fills at least part of a region of a stepped part in which the projecting part is provided. By doing so, even in a case where end parts of the second semiconductor chip are made slim due to the formation of the projecting part on the rear surface of the second semiconductor chip, it is possible to reinforce the end parts of the second semiconductor chip that have been made slim with the insulating resin.

A semiconductor device according to an aspect of the present invention includes a substrate provided with terminals for connecting conductive wires, a first semiconductor chip that is mounted face-up on the substrate, first electrode pads that are provided on the first semiconductor chip, first conductive wires that electrically connect the first electrode pads to the terminals provided on the substrate, and a second semiconductor chip that has a projecting part formed on a rear surface thereof. Second electrode pads are provided on the second semiconductor chip and an insulating resin encloses the first conductive wires on the first semiconductor chip and attaches the second semiconductor chip onto the first semiconductor chip via the projecting part. Second conductive wires electrically connect the second electrode pads and the terminals provided on the substrate. A sealing resin seals the first semiconductor chip to which the first conductive wires are connected and the second semiconductor chip to which the second conductive wires are connected.

In this way, by stacking the second semiconductor chip on the first semiconductor chip via the insulating resin, it is possible to maintain a fixed gap between the first semiconductor chip and the second semiconductor chip and to fix the first conductive wire on the first semiconductor chip with the insulating resin. This means that even in the case where the first semiconductor chip to which the first conductive wires are connected is sealed with resin, it is possible to prevent the first conductive wires from becoming deformed due to the injection pressure of the sealing resin. In this way, it is possible to stack the second conductive chip on the first conductive chip that has been connected by wire bonding while suppressing the increases in the number of processes, with it also being possible to prevent abnormal connections for the first conductive wires.

A semiconductor device according to an aspect of the present invention includes a substrate provided with terminals for connecting conductive wires, a first semiconductor chip that is mounted face-up on the substrate, first electrode pads that are provided on the first semiconductor chip, first conductive wires that electrically connect the first electrode pads to the terminals provided on the substrate, and a second semiconductor chip that has a projecting part formed on a rear surface thereof. Second electrode pads are provided on the second semiconductor chip. An insulating resin is provided between the first semiconductor chip and the second semiconductor chip so as to be present at least below the second electrode pads and attaches the second semiconductor chip onto the first semiconductor chip via the projecting part. Second conductive wires electrically connect the second electrode pads to the terminals provided on the substrate.

In this way, by stacking the second semiconductor chip on the first semiconductor chip via the insulating resin, it is possible to maintain a fixed gap between the first semiconductor chip and the second semiconductor chip and to support the region in which the second electrode pads are formed with the insulating resin. This means that even when second conductive wires are connected on the second electrode pads, it is possible to prevent damage to the second semiconductor chip due to ultrasonic vibration during wire bonding. While suppressing the increases in the number of processes, it is possible to stack the second semiconductor chip on a first semiconductor chip connected by wire bonding, and it is also possible to stably carry out the wire bonding.

A semiconductor device according to an aspect of the present invention further includes an insulating layer formed on an entire rear surface of the second semiconductor chip including the projecting part. By doing so, it is possible to avoid short circuits between the rear surface of the second semiconductor chip and the first conductive wires, even when the first conductive wires connected to the first semiconductor chip are high, and it is possible to stably stack the second semiconductor chip on the first semiconductor chip connected by wire bonding.

In a semiconductor device according to an aspect of the present invention, at least part of a region of the projecting part is formed so as to widen towards a surface on which the projecting part is formed. By doing so, it is possible to effectively dissipate the stress applied to the end parts of the second semiconductor chip, even when the end parts of the second semiconductor chip have been made slim due to the formation of the projecting part on the rear surface of the second semiconductor chip. This means that it is possible to improve the strength of the end parts of the second semiconductor chip while preventing the first conductive wire from contacting the rear surface of the second semiconductor chip.

In a semiconductor device according to an aspect of the present invention, a size of the second semiconductor chip is larger than a size of the first semiconductor chip. In this way, it is possible to dispose the second semiconductor chip on conductive wires that extend away from the first semiconductor chip without making the manufacturing process complex, and less space can be used when mounting semiconductor chips.

Also, a semiconductor device according to an aspect of the present invention includes a substrate provided with terminals for connecting conductive wiring, a first semiconductor chip that is mounted as a flip-chip on the substrate, a second semiconductor chip that is mounted face-up on the first semiconductor chip via an adhesive layer, and first conductive wires that electrically connect the terminals provided on the substrate and the second semiconductor chip. A third semiconductor chip has a projecting part formed on a rear surface thereof and is attached onto the second semiconductor chip via the projecting part. Second conductive wires electrically connect the terminals provided on the substrate and the third semiconductor chip.

In this way, by stacking the third semiconductor chip on the second semiconductor chip, it is possible to maintain a fixed gap between the second semiconductor chip and the third semiconductor chip, it is possible to fix the second semiconductor chip and the third semiconductor chip, and while suppressing the increases in height, it is possible to provide the first semiconductor chip between the second semiconductor chip and the substrate. This means that while suppressing the increases in the number of manufacturing processes, it is possible to stack the third semiconductor chip on the second semiconductor chip connected by wire bonding, to reduce the space used, and to increase the number of stacked semiconductor chips.

Also, an electronic device according to an aspect of the present invention includes a substrate provided with terminals for connecting conductive wires, a first electronic component that is mounted face-up on the substrate and is electrically connected to the terminals provided on the substrate by the conductive wires, and a second electronic component that has a projecting part formed on a rear surface thereof and is attached onto the first electronic component via the projecting part.

In this way, by stacking the second electronic component on the first electronic component, it is possible to fix the first electronic component and the second electronic component while maintaining a fixed gap between the first electronic component and the second electronic component. This means that while suppressing the increases in the number of manufacturing processes, it is possible to increase the gap between the first electronic component and the second electronic component and it is possible to connect the first electronic component by wire bonding, even in the case where the first electronic component and the second electronic component are the same size.

Also, an electronic appliance according to an aspect of the present invention includes a substrate provided with terminals for connecting conductive wires, a first semiconductor chip that is mounted face-up on the substrate and is electrically connected to the terminals provided on the substrate by the conductive wires, a second semiconductor chip that has a projecting part formed on a rear surface thereof and is attached onto the first semiconductor chip via the projecting part, and an electronic component that is electrically connected to the first semiconductor chip and the second semiconductor chip via the substrate.

In this way, it is possible to realize a stacked structure of semiconductor chips connected by wire bonding while suppressing the increases in the number of manufacturing processes, thereby reducing the cost of an electronic appliance.

Also, a method of manufacturing a semiconductor device according to an aspect of the present invention includes a step of mounting a first semiconductor chip on a substrate provided with terminals for connecting conductive wires, a step of connecting the first semiconductor chip mounted on the substrate and the terminals provided on the substrate with conductive wires, and a step of attaching a second semiconductor chip, that has a projecting part formed on a rear surface thereof, onto the first semiconductor chip.

In this way, it is possible to stack the second semiconductor chip on the first semiconductor chip that is connected by wire bonding while preventing the conductive wires connected to the first semiconductor chip from contacting the second semiconductor chip, and it is possible to lower the cost of a stacked structure of semiconductor chips connected by wire bonding.

Also, a method of manufacturing a semiconductor device according to an aspect of the present invention includes a step of mounting a first semiconductor chip on a substrate provided with terminals for connecting conductive wires, a step of connecting a first semiconductor chip mounted on the substrate and the terminals provided on the substrate with conductive wires, a step of disposing insulating resin on the first semiconductor chip, and a step of attaching a second semiconductor chip onto the first semiconductor chip by pressing a projecting part formed on a rear surface of the second semiconductor chip onto the insulating resin.

In this way, by stacking the second semiconductor chip on the first semiconductor chip, it is possible to attach the second semiconductor chip to the first semiconductor chip while making the insulating resin bulge from the projecting part. This means that it is possible to attach the second semiconductor chip onto the first semiconductor chip while filling a stepped part in a rear surface of the second semiconductor chip on which the projecting part is provided. This makes it possible to suppress the increases in the number of manufacturing processes, to improve the strength of end parts of the second semiconductor chip, and also to prevent the first conductive wire from contacting the rear surface of the second semiconductor chip.

Also, a method of manufacturing a semiconductor device according to an aspect of the present invention further comprises a step of half cutting a rear surface of a wafer, a surface of which has been divided by scribe lines, to form trenches that are disposed opposite the scribe lines, and a step of cutting the trenches along the scribe lines to form the second semiconductor chips that respectively have projecting parts formed on the rear surfaces thereof. By doing so, it is possible to form projecting parts on the rear surfaces of a plurality of semiconductor chips in a single operation and to stably stack the second semiconductor chip on the first semiconductor chip connected by wire bonding while preventing the manufacturing process from becoming complex.

Also, according to a method of manufacturing a semiconductor device according to an aspect of the present invention, the rear surface is half cut by one of dicing with a blade with a rounded tip, isotropic etching, and laser machining.

By doing so, it is possible to form projecting parts on rear surfaces of a plurality of semiconductor chips in a single operation and to make such projecting parts on the rear surfaces of the semiconductor chips curved. This means that even in the case where end parts of the semiconductor chips have been made slim due to the formation of the projecting parts on the rear surfaces of the semiconductor chips, it is possible to improve the strength of the end parts of the semiconductor chips while suppressing the increases in complexity for the manufacturing process, and it is possible to stably manufacture a stacked structure of semiconductor chips connected by wire bonding.

Also, a method of manufacturing a semiconductor device according to an aspect of the present invention further includes a step of forming an insulating film on a rear surface of the wafer in which the trenches have been formed. By doing so, it is possible to form, in a single operation, insulating films on entire rear surfaces of a plurality of semiconductor chips on which projecting parts are formed. This means that it is not necessary to separately form insulating films on respective second semiconductor chips to prevent short circuits between the first conductive wires and the rear surfaces of the second semiconductor chips, and it is possible to stably stack the second semiconductor chips on the first semiconductor chips that are connected by wire bonding while suppressing the increases in complexity for the manufacturing process.

### BRIEF DESCRIPTION OF THE DRAWINGS

FIG. 1 is a schematic cross-sectional view showing the construction of a semiconductor device according to a first embodiment.

FIGS. 2(a), 2(b) and 2(c) are a series of cross-sectional views showing a method of manufacturing the semiconductor device shown in FIG. 1.

FIGS. 3(a), 3(b), 3(c), 3(d) and 3(e) are a series of cross-sectional views showing a method of manufacturing the semiconductor device shown in FIG. 1.

FIG. 4 is a schematic cross-sectional view showing the construction of a semiconductor device according to a second embodiment.

FIGS. 5(a), 5(b), 5(c) and 5(d) are a series of cross-sectional views showing a method of manufacturing the semiconductor device shown in FIG. 4.

FIGS. 6(a), 6(b), 6(c) and 6(d) are a series of schematic cross-sectional views showing the construction of a semiconductor device according to a third embodiment.

FIGS. 7(a), 7(b), 7(c), 7(d) and 7(e) are a series of cross-sectional views showing a method of manufacturing the semiconductor device shown in FIGS. 6(a), 6(b), 6(c) and 6(d).

FIG. 8 is a schematic cross-sectional view showing the construction of a semiconductor device according to a fourth embodiment.

FIG. 9 is a schematic cross-sectional view showing the construction of a semiconductor device according to a fifth embodiment.

FIG. 10 is a schematic cross-sectional view showing the construction of a semiconductor device according to a sixth embodiment.

FIG. 11 is a schematic cross-sectional view showing the construction of a semiconductor device according to the related art.

### DESCRIPTION OF THE PREFERRED EMBODIMENTS

A semiconductor device and method of manufacturing the same according to embodiments of the present invention will now be described with reference to the attached drawings.

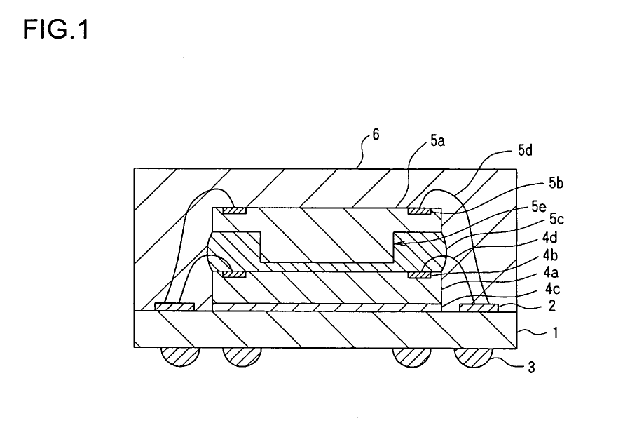

FIG. 1 is a schematic cross-sectional view showing the construction of a semiconductor device according to a first embodiment of the present invention.

In FIG. 1, lands 2 connected to conductive wires 4d, 5d are provided on a front surface of a carrier substrate 1, and projecting electrodes 3 are provided on a rear surface of the carrier substrate 1. It should be noted that it is possible to use a two-sided substrate, a multilayer circuit board, a build-up substrate, a tape substrate or a film substrate, for example, as the carrier substrate 1. As examples, polyimide resin, glass-epoxy resin, BT resin, a composite of aramid and epoxy, and ceramics and the like can be used as the material of the carrier substrate 1. Also, as examples, gold bumps, copper bumps or nickel bumps covered with a solder material or the like, or solder balls can be used as the projecting electrodes 3.

The semiconductor chips 4a, 5a are respectively provided with electrode pads 4b, 5b that connect to the conductive wires 4d, 5d, and a projecting part 5e that is integrally formed with the semiconductor chip 5a is provided on a rear surface of the semiconductor chip 5a. It should be noted that the thickness of the semiconductor chip 5a can be set in a range of around 50 to 200 μm, and the height of the projecting part 5e can be set in a range of around 30 to 150 μm, for example. Also, as examples, gold wires, aluminum wires, or the like can be used as the conductive wires 4d, 5d.

The semiconductor chip 4a is mounted face-up via an adhesive layer 4c on the carrier substrate 1. In addition, the semiconductor chip 5a is mounted face-up via the projecting part 5e on the semiconductor chip 4a, with the projecting part 5e being attached to the semiconductor chip 4a via the insulating resin 5c. It should be noted that a paste-type resin or a sheet-type resin may be used as the insulating resin 5c, and as examples, epoxy resin, acrylic resin, or maleimide resin may be used. It is also possible to mix filler, such as silica or alumina, into the insulating resin 5c. By doing so, it is possible to reduce the hydrophilia of the insulating resin 5c and to make the linear expansion coefficient of the insulating resin 5c closer to that of the semiconductor chips 4a, 5a. This makes it possible to ease the stress caused by the insulating resin 5c and thereby improve the reliability of the semiconductor device.

The semiconductor chip 4a mounted on the carrier substrate 1 is electrically connected to the lands 2 of the carrier substrate 1 via the conductive wires 4d and the semiconductor chip 5a that is stacked on top of the semiconductor chip 4a via the projecting part 5e is electrically connected to the lands 2 of the carrier substrate 1 via the conductive wires 5d. The semiconductor chips 4a, 5a to which the conductive wires 4d, 5d are respectively connected are sealed by a sealing resin 6.

Here, in the case where the semiconductor chip 5a is stacked on top of the semiconductor chip 4a, the height of the projecting part 5e can be set so that the conductive wires 4d do not contact the rear surface of the semiconductor chip 5a. The projecting part 5e can be disposed on the semiconductor chip 4a so as to avoid the conductive wires 4d connected to the semiconductor chip 4a.

By stacking the semiconductor chip 5a on the semiconductor chip 4a in this way, it is possible to fix the semiconductor chips 4a, 5a while preventing the conductive wires 4d from contacting the rear surface of the semiconductor chip 5a. This means that even when the sizes of the semiconductor chips 4a, 5a are the same, it is possible to stack the semiconductor chip 5a on the semiconductor chip 4a to which the conductive wires 4d are connected while suppressing the increases in the number of manufacturing processes.

In the case where the projecting part 5e is attached on the semiconductor chip 4a by the insulating resin 5c, by having the insulating resin 5c disposed on the semiconductor chip 4a bulge out around the projecting part 5e, it is possible to fill a stepped part on the rear surface of the semiconductor chip 5a on which the projecting part 5e is formed with insulating resin 5c, so that the conductive wires 4d on the semiconductor chip 4a can be enclosed.

By doing so, it is possible to maintain a fixed gap between the semiconductor chips 4a, 5a and to fix the conductive wires 4d on the semiconductor chip 4a with the insulating resin 5c. This means that even in the case where the semiconductor chip 4a connected to the conductive wires 4d is sealed with resin, it is possible to prevent the conductive wires 4d from being moved by the injection pressure of the sealing resin 6. Also, while suppressing the increases in the number of manufacturing processes, it is possible to stack the semiconductor chip 5a on the semiconductor chip 4a that is connected by wire bonding. It is also possible to prevent abnormal contact of the conductive wires 4d.

A space between the semiconductor chips 4a, 5a can be filled with the insulating resin 5c so that the insulating resin 5c is also present below the electrode pads 5b of the semiconductor chip 5a. By doing so, it is possible to maintain a fixed gap between the semiconductor chips 4a, 5a and to support a region in which the electrode pads 5b are formed with the insulating resin 5c. This means that even in the case where the conductive wires 5d are connected to the electrode pads 5b, it is possible to prevent damage to the semiconductor chip 5a due to ultrasonic vibrations during wire bonding. While suppressing the increases in the number of manufacturing processes, it is possible to stack the semiconductor chip 5a on the semiconductor chip 4a connected by wire bonding, so that wire bonding can be carried out stably.

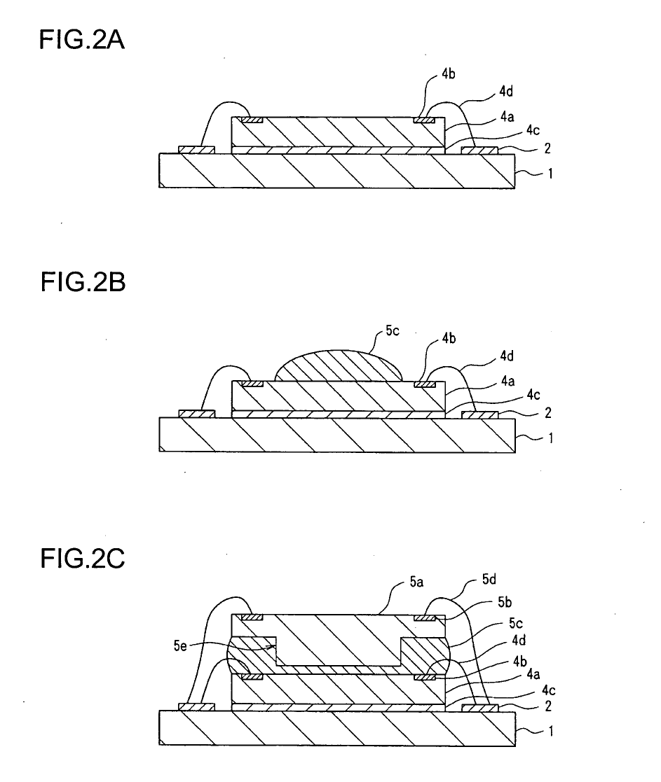

FIGS. 2(a)-2(c) are a series of cross-sectional views showing a method of manufacturing the semiconductor device shown in FIG. 1.

In FIG. 2(a), the semiconductor chip 4a is mounted face-up on the carrier substrate 1 via the adhesive layer 4c. By wire bonding the semiconductor chip 4a mounted face-up on the carrier substrate 1, the lands 2 and the electrode pads 4b can be connected by the conductive wires 4d.

Next, as shown in FIG. 2(b), the insulating resin 5c is disposed on the semiconductor chip 4a to which the conductive wire 4d is connected. It should be noted that when disposing the insulating resin 5c on the semiconductor chip 4a, it is possible to use a dispenser, for example.

Next, as shown in FIG. 2(c), while pressing the insulating resin 5c against the rear surface of the semiconductor chip 5a on which the projecting part 5e is formed, the semiconductor chip 5a is mounted face-up on the semiconductor chip 4a. Here, while adjusting the amount of insulating resin 5c disposed on the semiconductor chip 4a and mounting the semiconductor chip 5a on the semiconductor chip 4a, the insulating resin 5c provided on the semiconductor chip 4a can be made to bulge out around the projecting part 5e.

By doing so, by mounting the semiconductor chip 4a on the semiconductor chip 5a, it is possible to fill a stepped part on the rear surface of the semiconductor chip 5a on which the projecting part 5e is formed with the insulating resin 5c. This means that without increasing the number of manufacturing processes, it is possible to enclose the conductive wires 4d on the semiconductor chip 4a with the insulating resin 5c and to reinforce the space below the electrode pads 5b of the semiconductor chip 5a with the insulating resin 5c.

In a state where the semiconductor chip 5a is stacked on the semiconductor chip 4a via the projecting part 5e, the insulating resin 6 is hardened. After this, by carrying out wire bonding for the semiconductor chip 5a mounted face-up on the semiconductor chip 4a, the lands 2 and the electrode pads 5b are connected by the conductive wires 5d. Here, by filling parts of a rear surface of the semiconductor chip 5a corresponding to positions of the electrode pads 5b with the insulating resin 5c, it is possible to reinforce the space below the electrode pads 5b of the semiconductor chip 5a with the insulating resin 5c. This means that even when the conductive wires 5d are connected on the electrode pad 5b, it is possible to prevent damage to the semiconductor chip 5a by ultrasonic vibrations during wire bonding, and wire bonding can be carried out stably while suppressing the increases in the number of manufacturing processes.

It should be noted that when the semiconductor chip 5a is attached onto the semiconductor chip 4a via the insulating resin 5c, it is possible to use an adhesive joint, such as an Anisotropic Conductive Film (ACF) joint, a Nonconductive Film (NCF) joint, an Anisotropic Conductive Paste (ACP) joint, or a Nonconductive Paste (NCP) joint.

Next, as shown in FIG. 1, using a method such as transfer molding, the semiconductor chips 4a, 5a to which the conductive wires 4d, 5d are respectively connected are sealed using the sealing resin 6. Here, by filling the rear surface of the semiconductor chip 5a with the insulating resin 5c so as to enclose the conductive wires 4d on the semiconductor chip 4a, it is possible to fix the conductive wires 4d on the semiconductor chip 4a with the insulating resin 5c. This means that even when the semiconductor chip 4a to which the conductive wires 4d are connected is sealed with resin, it is possible to prevent the conductive wires 4d from being moved by the injection pressure of the sealing resin 6. Also, while suppressing the increases in the number of manufacturing processes, it is possible to stack the semiconductor chip 5a on the semiconductor chip 4a that is connected by wire bonding and also possible to prevent abnormal contact of the conductive wires 4d.

It should be noted that when the insulating resin 5c is provided between the semiconductor chips 4a, 5a, in place of providing the insulating resin 5c on the semiconductor chip 4a, it is possible to use a method such as printing or dipping, so that the insulating resin 5c adheres to the projecting part 5e.

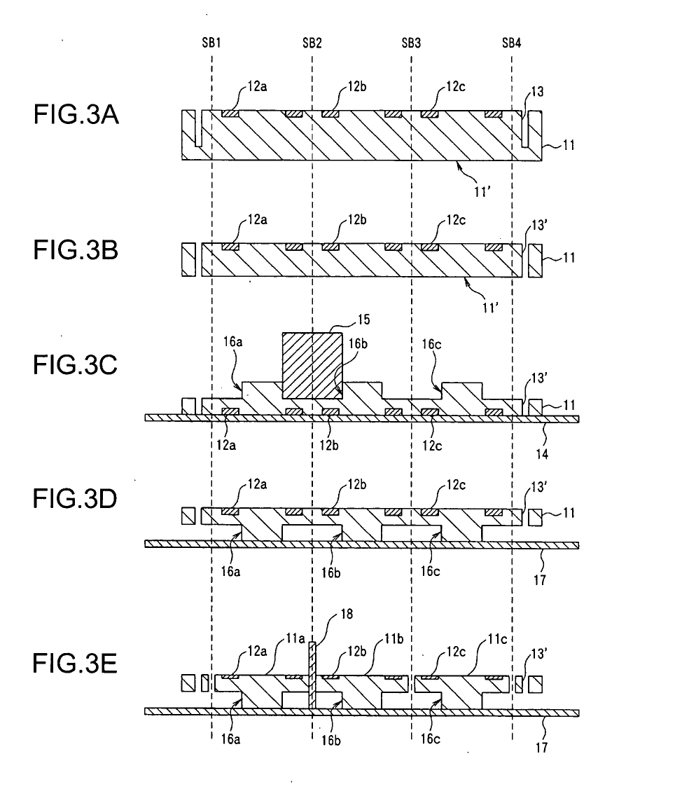

FIGS. 3(a)-3(e) are a series of cross-sectional views showing the method of manufacturing the projecting part of the semiconductor device shown in FIG. 1.

In FIG. 3(a), a surface of a semiconductor wafer 11 is divided by scribe lines SB1 to SB4, and active surfaces are respectively formed in the divided regions marked by the scribe lines SB1 to SB4. In addition, electrode pads 12a to 12c are respectively provided. Openings 13 are also provided in the semiconductor wafer 11 avoiding the active surfaces formed on the semiconductor wafer 11.

Next, as shown in FIG. 3(b), a rear surface 11′ of the semiconductor wafer 11 in which the openings 13 have been formed is ground to make the semiconductor wafer 11 slim, and by having the openings 13 pass through the semiconductor wafer 11, through-holes 13′ are formed in the semiconductor wafer 11. It should be noted that the openings may pass through the semiconductor wafer 11 in advance.

Next, as shown in FIG. 3(c), dicing tape 14 is stuck onto the active surface-side of the semiconductor wafer 11 in which the through-holes 13′ have been formed. By positioning a blade 15 while referring to the through-holes 13′, the center of the blade 15 is disposed so as to correspond to positions of the scribe lines SB1 to SB4. After this, by half-cutting the rear surface of the semiconductor wafer 11 using the blade 15, trenches are formed in the rear surface of the semiconductor wafer 11, and projecting parts 16a to 16c are formed in the divided regions produced by the scribe lines SB1 to SB4. It should be noted that in the case where a dicing apparatus that can position the blade 15 on the rear surface of the semiconductor wafer 11 while looking at the active surface-side of the semiconductor wafer 11 is used, the through-holes 13′ do not definitely need to be formed.

Here, the depth of the trenches formed in the rear surface of the semiconductor wafer 11 can be set so that when the semiconductor chips 11a to 11c formed with the projecting parts 16a to 16c are stacked on lower-level semiconductor chips connected by wire bonding, the conductive wires connected to the lower-level semiconductor chips do not contact the rear surfaces of the semiconductor chips 11a to 11c. The width of the blade 15 can be set so that the semiconductor chips 11a to 11c on which the projecting parts 16a to 16c are formed can be disposed on lower-level semiconductor chips while avoiding conductive wires connected to the lower-level semiconductor chips.

Next, as shown in FIG. 3(d), the dicing tape 14 is peeled off the semiconductor wafer 11 on which the projecting parts 16a to 16c are formed, and dicing tape 17 is stuck onto a rear surface of the semiconductor wafer 11 via the projecting parts 16a to 16c.

Next, as shown in FIG. 3(e), a full cutting of the semiconductor wafer 11 is carried out along the scribe lines SB1 to SB4 using a blade 18, which is narrower than the blade 15, to form the semiconductor chips 11a to 11c that have the projecting parts 16a to 16c respectively formed on their rear surfaces.

By doing so, it is possible to form the projecting parts 16a to 16c on the rear surfaces of the plurality of semiconductor chips 11a to 11c in a single operation, and it is possible to stably stack the semiconductor chips 11a to 11c on lower-level semiconductor chips connected by wire bonding, while preventing the manufacturing process from becoming complex.

It should be noted that in the case where the semiconductor chips 11a to 11c provided with the projecting parts 16a to 16c are formed, it is possible to half cut the surface of the semiconductor wafer 11 along the scribe lines SB1 to SB4 using the blade 18 and then half cut the rear surface of the semiconductor wafer 11 using the blade 15.

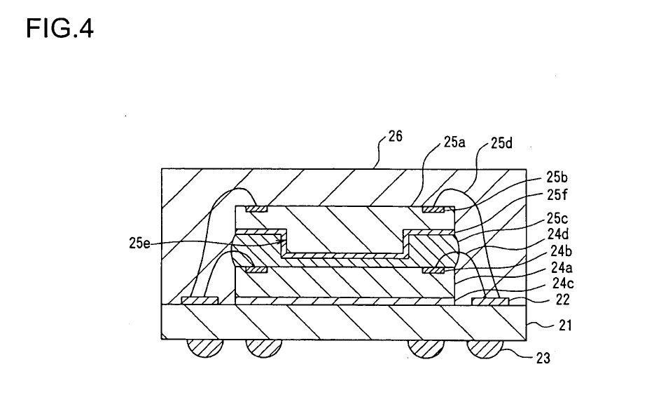

FIG. 4 is a schematic cross-sectional view showing the construction of a semiconductor device according to a second embodiment of the present invention.

In FIG. 4, lands 22 that connect conductive wires 24d, 25d are provided on a front surface of a carrier substrate 21 and projecting electrodes 23 are provided on a rear surface of the carrier substrate 21. Also, electrode pads 24b, 25b that connect the conductive wires 24d, 25d are respectively formed on semiconductor chips 24a, 25a, and a projecting part 25e, which is integrally formed with the semiconductor chip 25a, is provided on a rear surface of the semiconductor chip 25a. An insulating layer 25f is also formed on the entire rear surface of the semiconductor chip 25a which includes the projecting part 25e. It should be noted that as examples, a silicon oxide film, a silicon nitride film or the like can be used as the insulating layer 25f.

Here, by forming the insulating layer 25e on the entire rear surface of the semiconductor chip 25a which includes the projecting part 25e, it is possible to prevent a short circuit occurring between the conductive wires 24d and the rear surface of the semiconductor chip 25a, even in the case where the conductive wires 24d that are connected to the semiconductor chip 24a are high.

Next, the semiconductor chip 24a is mounted face-up on the carrier substrate 21 via an adhesive layer 24c. Also, the semiconductor chip 25a is mounted face-up on the semiconductor chip 24a via the projecting part 25e, and the projecting part 25e is attached to the semiconductor chip 24a via insulating resin 25c. Here, by making the insulating resin 25c bulge out around the projecting part 25e, it is possible to fill a stepped part on a rear surface of the semiconductor chip 25a on which the projecting part 25e is formed with the insulating resin 25c, so that it is possible to enclose the conductive wires 24d on the semiconductor chip 24a with the insulating resin 25c and to reinforce the space below electrode pads 25b of the semiconductor chip 25a with the insulating resin 25c.

Also, the semiconductor chip 24a mounted on the carrier substrate 21 can be electrically connected to the lands 22 of the carrier substrate 21 via the conductive wires 24d and the semiconductor chip 25a stacked on the semiconductor chip 24a via the projecting part 25e can also be electrically connected to the lands 22 of the carrier substrate 21 via the conductive wires 25d. The semiconductor chips 24a, 25a, to which the conductive wires 24d, 25d are respectively connected, are sealed by sealing resin 26.

It should be noted that the height of the projecting part 25e can be set so that in the case where the semiconductor chip 25a is stacked on the semiconductor chip 24a, the conductive wires 24d do not contact the rear surface of the semiconductor chip 25a. The projecting part 25e can also be disposed on the semiconductor chip 24a so as to avoid the conductive wires 24d connected to the semiconductor chip 24a.

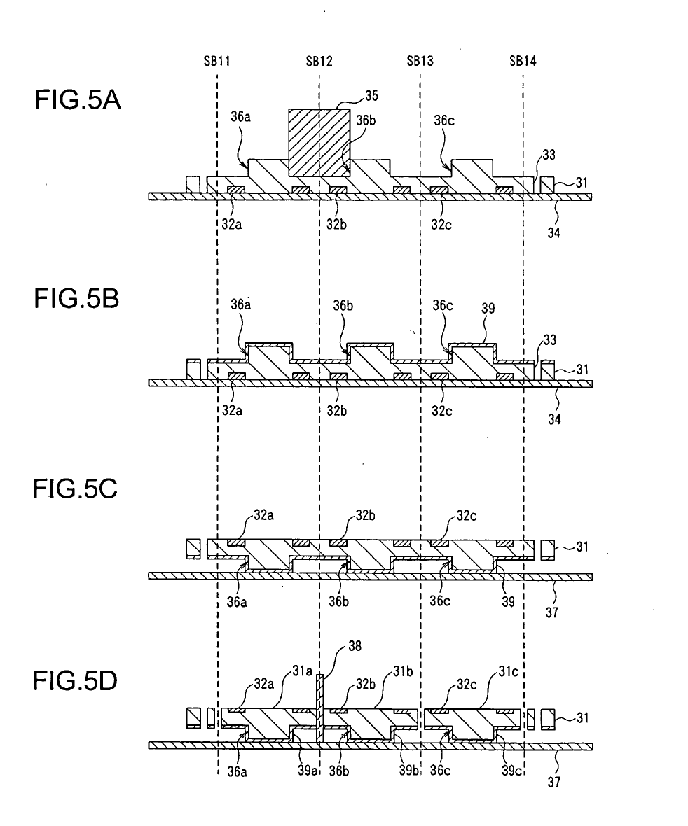

FIGS. 5(a)-5(d) are a series of cross-sectional views showing a method of manufacturing the projecting part of the semiconductor device shown in FIG. 4.

In FIG. 5(a), the surface of a semiconductor wafer 31 is divided by scribe lines SB11 to SB14, active surfaces are respectively formed in the divided regions marked by the scribe lines SB11 to SB14, and electrode pads 32a to 32c are respectively provided in the regions. Through-holes 33 are also formed in the semiconductor wafer 31 so as to avoid the active surfaces formed on the semiconductor wafer 31.

Next, dicing tape 34 is stuck onto the active surface-side of the semiconductor wafer 31 in which the through-holes 33 is formed. By positioning a blade 35 while referring to the through-holes 33, the center of the blade 35 is disposed so as to correspond to positions of the scribe lines SB11 to SB14. After this, by half-cutting the rear surface of the semiconductor wafer 31 using the blade 35, trenches are formed in the rear surface of the semiconductor wafer 31, and projecting parts 36a to 36c are formed in the divided regions produced by the scribe lines SB11 to SB14.

Here, the depth of the trenches formed in the rear surface of the semiconductor wafer 31 can be set so that when the semiconductor chips 31a to 31c formed with the projecting parts 36a to 36c are stacked on lower-level semiconductor chips connected by wire bonding, the conductive wires connected to the lower-level semiconductor chips do not contact rear surfaces of the semiconductor chips 31a to 31c. The width of the blade 35 can be set so that the semiconductor chips 31a to 31c, on which the projecting parts 36a to 36c are formed, can be disposed on lower-level semiconductor chips while avoiding conductive wires connected to the lower-level semiconductor chips.

Next, as shown in FIG. 5(b), an insulating layer 39 is formed on the entire rear surface of the semiconductor wafer 31 including the surfaces of the projecting parts 36a to 36c by a method such as CVD.

Next, as shown in FIG. 5(c), the dicing tape 34 is peeled off the semiconductor wafer 31 on which the projecting parts 36a to 36c are formed, and dicing tape 37 is stuck onto a rear surface of the semiconductor wafer 31 via the projecting parts 36a to 36c.

Next, as shown in FIG. 5(d), a full cutting of the semiconductor wafer 31 is carried out along the scribe lines SB11 to SB14 using a blade 38, which is narrower than the blade 35, to form the semiconductor chips 31a to 31c that are respectively provided with the projecting parts 36a to 36c and insulating layers 39a to 39c.

By doing so, it is possible to form, in a single operation, the insulating layers 39a to 39c on the entire rear surfaces of the plurality of semiconductor chips 31a to 31c on which the projecting parts 36a to 36c are respectively formed. This means that it is not necessary to separately form the insulating layers 39a to 39c on the respective semiconductor chips 31a to 31c to prevent short circuits between the conductive wires connected to the lower-level semiconductor chips and the rear surfaces of the semiconductor chips 31a to 31c and it is possible to stably stack the semiconductor chips 31a to 31c on lower-level semiconductor chips connected by wire bonding while preventing the manufacturing process from becoming complex.

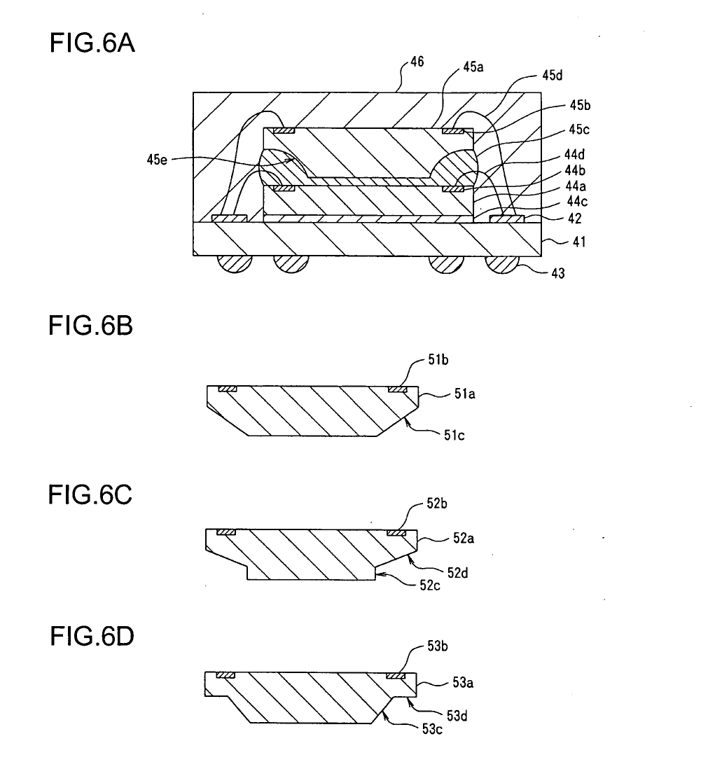

FIGS. 6(a)-6(d) are a schematic cross-sectional views showing the construction of a semiconductor device according to a third embodiment of the present invention.

In FIG. 6(a), lands 42 that connect conductive wires 44d, 45d are provided on a surface of a carrier substrate 41, and projecting electrodes 43 are provided on a rear surface of the carrier substrate 41. Electrode pads 44b, 45b that connect conductive wires 44d, 45d are also respectively provided on semiconductor chips 44a, 45a, and a projecting part 45e that is integrally formed with the semiconductor chip 45a is provided on a rear surface of the semiconductor chip 45a. Here, at least a partial region of the projecting part 45e can be formed so as to widen towards the surface on which the projecting part 45e is formed, and as one example, the projecting part 45e can be formed with a curved shape.

By doing so, in the case where end parts of the semiconductor chip 45a have been made slim due to the formation of the projecting part 45e on the rear surface of the semiconductor chip 45a, the stress applied to end parts of the semiconductor chip 45a can be effectively dissipated. This means that the strength of the end parts of the semiconductor chip 45a can be increased while preventing the conductive wires 44d connected to the semiconductor chip 44a from contacting the rear surface of the semiconductor chip 45a, which makes it possible to prevent damage to the semiconductor chip 45a due to ultrasonic vibrations and the like during wire bonding.

Next, the semiconductor chip 44a is mounted face-up on the carrier substrate 41 via an adhesive layer 44c. In addition, the semiconductor chip 45a is mounted face-up on the semiconductor chip 44a via the projecting part 45e, with the projecting part 45e being attached onto the semiconductor chip 44a by insulating resin 45c. Here, by having the insulating resin 45c bulge out around the projecting part 45e, it is possible to fill a stepped part in a rear surface of the semiconductor chip 45a on which the projecting part 45e is formed with the insulating resin 45c, so that it is possible to enclose the conductive wires 44d on the semiconductor chip 44a with the insulating resin 45c and to reinforce spaces below electrode pads 45b of the semiconductor chip 45a with the insulating resin 45c.

The semiconductor chip 44a mounted on the carrier substrate 41 is electrically connected to the lands 42 of the carrier substrate 41 via the conductive wires 44d and the semiconductor chip 45a stacked on the semiconductor chip 44a via the projecting part 45e is electrically connected to the lands 42 of the carrier substrate 41 via the conductive wires 45d. The semiconductor chips 44a, 45a to which the conductive wires 44d, 45d are respectively connected are sealed by sealing resin 46.

Here, in the case where the semiconductor chip 45a is stacked on top of the semiconductor chip 44a, the height of the projecting part 45e can be set so that the conductive wires 44d do not contact the rear surface of the semiconductor chip 45a. The projecting part 45e can be disposed on the semiconductor chip 44a so as to avoid the conductive wires 44d connected to the semiconductor chip 44a.

It should be noted that although a method for making at least a partial region of the projecting part 45e in a curved shape is described in the embodiment shown in FIG. 6(a), as shown in FIG. 6(b) it is possible to provide inclined surfaces 51c in at least part of a rear surface of a semiconductor chip 51a that has electrode pads 51b formed on a front surface thereof. Also, as shown in FIG. 6(c), it is possible to provide, via inclined surfaces 52d, a projecting part 52c in at least a partial region of a rear surface of a semiconductor chip 52a that has electrode pads 52b formed on a front surface thereof. Also, as shown in FIG. 6(d), it is possible to provide, via flat surfaces 53d, a projecting part 53c with inclined surfaces in at least a partial region of the rear surface of the semiconductor chip 53a that has electrode pads 53b formed on a front surface thereof.

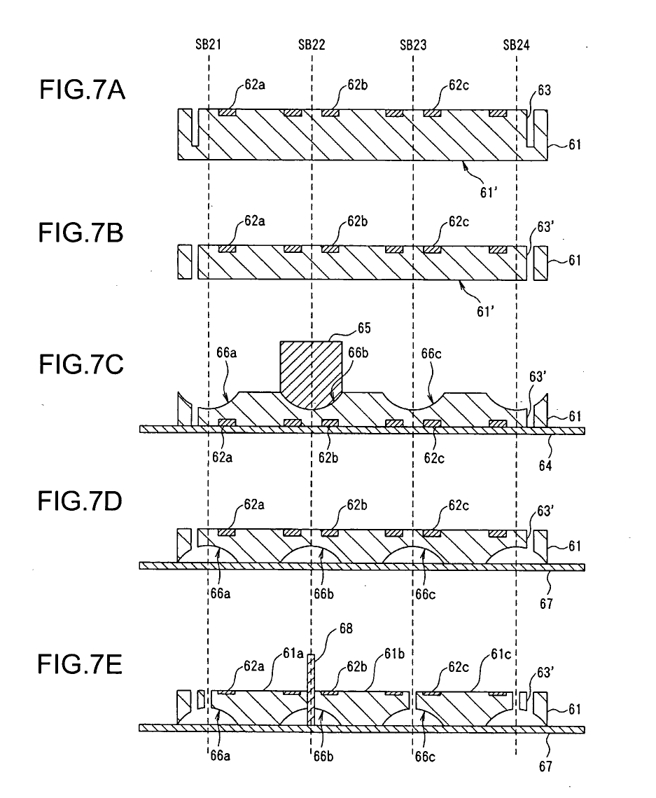

FIGS. 7(a)-7(e) are a series of cross-sectional views showing a method of manufacturing a projecting part of the semiconductor device shown in FIGS. 6(a)-6(d).

In FIG. 7(a), a surface of a semiconductor wafer 61 is divided by scribe lines SB21 to SB24, active surfaces are respectively formed in the divided regions marked by the scribe lines SB21 to SB24, and electrode pads 62a to 62c are respectively provided in these regions. Openings 63 are also provided in the semiconductor wafer 61 so as to avoid the active surfaces formed on the semiconductor wafer 61.

Next, as shown in FIG. 7(b), a rear surface 61′ of the semiconductor wafer 61 in which the openings 63 are formed is ground to make the semiconductor wafer 61 slim, and by passing the opening 63 through the semiconductor wafer 61, through-holes 63′ are formed in the semiconductor wafer 61.

Next, as shown in FIG. 7(c), dicing tape 64 is stuck onto the active surface-side of the semiconductor wafer 61 in which the through-holes 63′ are formed. By positioning a blade 65 while referring to the through-holes 63′, the center of the blade 65 is disposed so as to correspond to positions of the scribe lines SB21 to SB24. Here, the tip of the blade 65 can have a rounded shape. After this, by half-cutting the rear surface of the semiconductor wafer 61 using the blade 65, curved trenches are formed in the rear surface of the semiconductor wafer 61, and curved projecting parts 66a to 66c are formed in the respective divided regions produced by the scribe lines SB21 to SB24.

Here, the depth of the trenches formed in the rear surface of the semiconductor wafer 61 can be set so that when the semiconductor chips 61a to 61c formed with the projecting parts 66a to 66c are stacked on lower-level semiconductor chips connected by wire bonding, the conductive wires connected to the lower-level semiconductor chips do not contact rear surfaces of the semiconductor chips 61a to 61c. The width of the blade 65 can be set so that the semiconductor chips 61a to 61c on which the projecting parts 66a to 66c are formed can be disposed on lower-level semiconductor chips while avoiding conductive wires connected to the lower-level semiconductor chips.

Next, as shown in FIG. 7(d), the dicing tape 64 is peeled off the semiconductor wafer 61 on which the projecting parts 66a to 66c are formed and dicing tape 67 is stuck onto the rear surface of the semiconductor wafer 61 via the projecting parts 66a to 66c.

Next, as shown in FIG. 7(e), a full cutting of the semiconductor wafer 61 is carried out along the scribe lines SB21 to SB24 using a blade 68, which is narrower than the blade 65, to form the semiconductor chips 61a to 61c that have the curved projecting parts 66a to 66c respectively formed on the rear surface.

By doing so, it is possible to make the projecting parts 66a to 66c formed on the rear surfaces of the semiconductor chips 61a to 61c curved and to form the projecting parts 66a to 66c on the rear surfaces of the semiconductor chips 61a to 61c in a single operation. This means that even when the end parts of the semiconductor chips 61a to 61c have been made slim due to the formation of the projecting parts 66a to 66c on the rear surface of the semiconductor chips 61a to 61c, it is possible to improve the strength of the end parts of the semiconductor chips 61a to 61c and to stably manufacture a stacked structure of semiconductor chips connected by wire bonding, while preventing the manufacturing process from becoming complex.

It should be noted that in the embodiment shown in FIGS. 7(a)-7(e), a method in which the projecting parts 66a to 66c with curved shapes are formed by dicing using a blade with a rounded tip is described, the projecting parts 66a to 66c with curved shapes may be formed by isotropic etching or laser machining. By appropriately changing the shape of the tip of the blade, it is possible to form the projecting parts 66a to 66c with shapes corresponding to the shape of the tip of the blade.

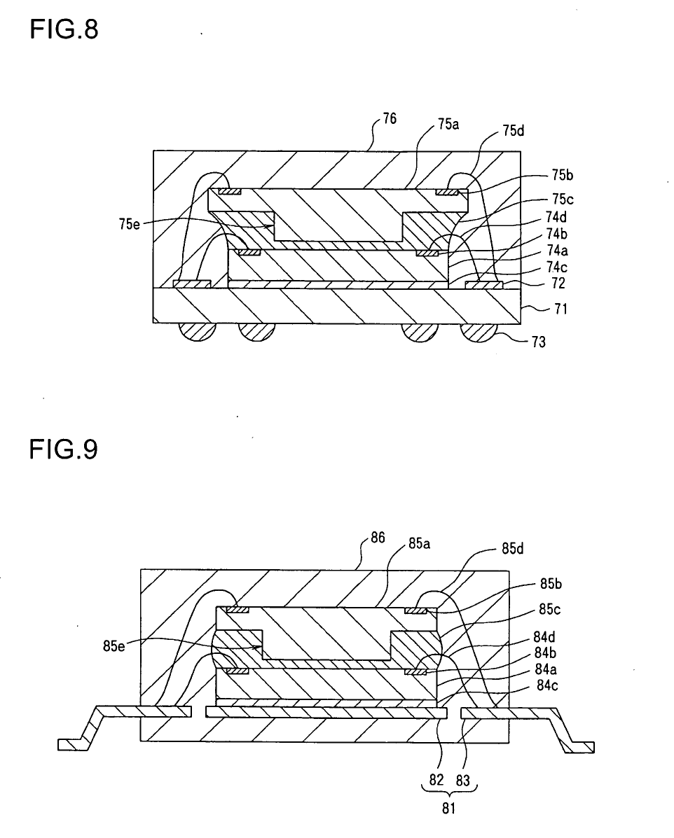

FIG. 8 is a schematic cross-sectional view showing the construction of a semiconductor device according to a fourth embodiment of the present invention.

In FIG. 8, lands 72 that connect conductive wires 74d, 75d are provided on a front surface of a carrier substrate 71 and projecting electrodes 73 are provided on a rear surface of the carrier substrate 71. Also, electrode pads 74b, 75b that connect the conductive wires 74d, 75d are respectively provided on semiconductor chips 74a, 75a, and a projecting part 75e, which is integrally formed with the semiconductor chip 75a, is provided on a rear surface of the semiconductor chip 75a. The size of the semiconductor chip 75a can be made larger than the size of the semiconductor chip 74a.

Next, the semiconductor chip 74a is mounted face-up on the carrier substrate 71 via an adhesive layer 74c. Also, the semiconductor chip 75a is mounted face-up on the semiconductor chip 74a via the projecting part 75e, the projecting part 75e is attached to the semiconductor chip 74a by insulating resin 75c, and end parts of the semiconductor chip 75a are disposed over the conductive wires 74d that extend away from the semiconductor chip 74a. By doing so, it is possible to effectively use spaces above wiring regions of the conductive wires 74d and to reduce the space used when mounting the semiconductor chip 75a without making the manufacturing process complex.

Here, by having the insulating resin 75c bulge out around the projecting part 75e, it is possible to fill a stepped part of the rear surface of the semiconductor chip 75a on which the projecting part 75e is formed with the insulating resin 75c and thereby surround the conductive wires 74d on the semiconductor chip 74a with the insulating resin 75c and reinforce spaces below the electrode pads 75b of the semiconductor chip 75a with the insulating resin 75c.

The semiconductor chip 74a that is mounted on the carrier substrate 71 is electrically connected via the conductive wires 74d to lands 72 of the carrier substrate 71 and the semiconductor chip 75a that is stacked on the semiconductor chip 74a via the projecting part 75e is electrically connected via the conductive wires 75d to the lands 72 of the carrier substrate 71. The semiconductor chips 74a, 75a to which the conductive wires 74d, 75d are respectively connected are sealed by sealing resin 76.

Here, in the case where the semiconductor chip 75a is stacked on top of the semiconductor chip 74a, the height of the projecting part 75e can be set so that the conductive wires 74d do not contact the rear surface of the semiconductor chip 75a. The projecting part 75e can be disposed on the semiconductor chip 74a so as to avoid the conductive wires 74d connected to the semiconductor chip 74a.

FIG. 9 is a schematic cross-sectional view showing the construction of a semiconductor device according to a fifth embodiment of the present invention.

In FIG. 9, a die-pad 82, which die-bonds a semiconductor chip 84a, is provided on a lead frame 81 that is also provided with leads 83 that connect conductive wires 84d, 85d. Electrode pads 84b, 85b that connect the conductive wires 84d, 85d are respectively provided on semiconductor chips 84a, 85a, and a projecting part 85e that is integrally formed with the semiconductor chip 85a is provided on a rear surface of the semiconductor chip 85a.

Next, the semiconductor chip 84a is mounted face-up on the die-pad 82 of the lead frame 81 via an adhesive layer 84c. The semiconductor chip 85a is mounted face up on the semiconductor chip 84a via the projecting part 85e and the projecting part 85e is attached onto the semiconductor chip 84a by the insulating resin 85c.

The semiconductor chip 84a die-bonded on the die-pad 82 is electrically connected to the leads 83 of the lead frame 81 via the conductive wires 84d and the semiconductor chip 85a stacked on the semiconductor chip 84a via the projecting part 85e is electrically connected to the leads 83 of the lead frame 81 via the conductive wires 85d. Also, the semiconductor chips 84a, 85a to which the conductive wires 84d, 85d are connected are sealed by sealing resin 86.

Here, in the case where the semiconductor chip 85a is stacked on top of the semiconductor chip 84a, the height of the projecting part 85e can be set so that the conductive wires 84d do not contact the rear surface of the semiconductor chip 85a. The projecting part 85e can be disposed on the semiconductor chip 84a so as to avoid the conductive wires 84d connected to the semiconductor chip 84a. Here, by making the insulating resin 85c bulge out around the projecting part 85e, it is possible to fill a stepped part on a rear surface of the semiconductor chip 85a on which the projecting part 85e is formed with the insulating resin 85c, and thereby enclose the conductive wires 84d on the semiconductor chip 84a with the insulating resin 85c and reinforce the spaces below electrode pads 85b of the semiconductor chip 85a with the insulating resin 85c.

In this way, even in the case where a stacked structure of the semiconductor chips 84a, 85a is mounted on the lead frame 81, it is possible to stack the semiconductor chip 85a on the semiconductor chip 84a to which the conductive wires 84d are connected while preventing the conductive wires 84d from contacting the rear surface of the semiconductor chip 85a. By doing so, it is possible to reduce the cost of the semiconductor device.

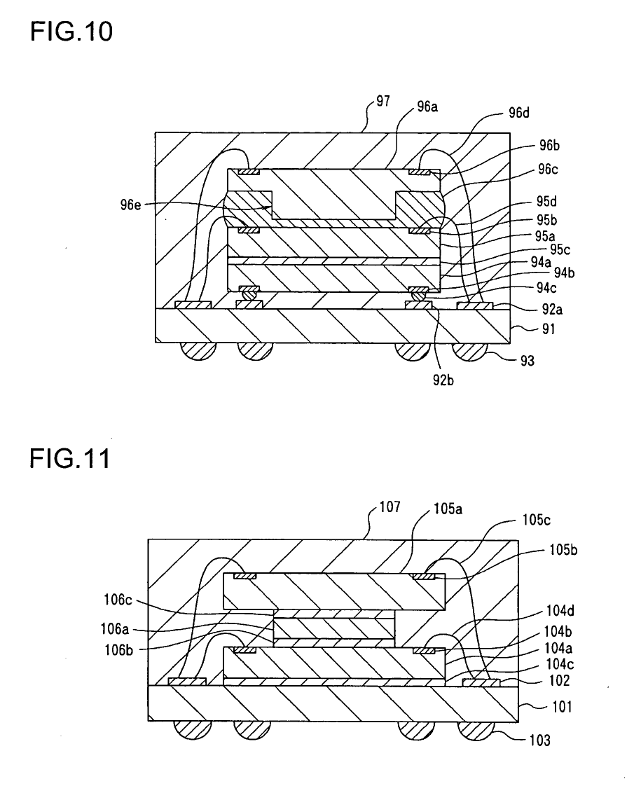

FIG. 10 is a schematic cross-sectional view showing the construction of a semiconductor device according to a sixth embodiment of the present invention.

In FIG. 10, lands 92a that connect conductive wires 95d, 96d and lands 92b joined to projecting electrodes 94c are provided on a surface of a carrier substrate 91, and projecting electrodes 93 are provided on a rear surface of the carrier substrate 91. Electrode pads 94b, on which the projecting electrodes 94c are disposed, are provided on the semiconductor chip 94a. Electrode pads 95b, 96b that connect the conductive wires 95d, 96d are respectively provided on the semiconductor chip 95a, 96a and a projecting part that is integrally formed with the semiconductor chip 96a is provided on a rear surface of the semiconductor chip 96a. It should be noted that gold bumps, copper bumps or nickel bumps covered with a solder material or the like, or solder balls can be used as examples of the projecting electrodes 93, 94c.

The semiconductor chip 94a is mounted via the projecting electrode 94c on the carrier substrate 91 as a flip-chip. It should be noted that in the case where the semiconductor chip 94a is mounted via the projecting electrodes 94c on the carrier substrate 91 as a flip-chip, it is possible to use adhesive joints, such as ACF joints, NCF joints, ACP joints, or NCP joints, for example, or metal joints such as solder joints or alloy joints.

The semiconductor chip 95a is mounted face-up via the adhesive resin 95c on a rear surface of the semiconductor chip 94a mounted as a flip-chip. In addition, the semiconductor chip 96a is mounted face-up via the projecting part 96e on the semiconductor chip 95a, and the projecting part 96e is attached onto the semiconductor chip 95a by insulating resin 96c.

The semiconductor chip 95a, which is mounted on the rear surface of the semiconductor chip 94a, is electrically connected to the lands 92a of the carrier substrate 91 via the conductive wires 95d, and the semiconductor chip 96a, which is stacked on the semiconductor chip 95a via the insulating resin 97 is electrically connected to the lands 92a of the carrier substrate 91 via the conductive wires 96d. The semiconductor chip 94a mounted as a flip-chip and the semiconductor chips 95a, 96a to which the conductive wires 95d, 96d are respectively connected are sealed by sealing resin 97.

Here, in the case where the semiconductor chip 96a is stacked on top of the semiconductor chip 95a, the height of the projecting part 96e can be set so that the conductive wires 95d do not contact the rear surface of the semiconductor chip 96a. The projecting part 96e can be disposed on the semiconductor chip 95a so as to avoid the conductive wire 95d connected to the semiconductor chip 95a. Also, by having the insulating resin 96c bulge out around the projecting part 96e, it is possible to fill a stepped part on the rear surface of the semiconductor chip 96a on which the projecting part 96e is formed with the insulating resin 96c, so that the conductive wires 95d on the semiconductor chip 95a can be enclosed in the insulating resin 96c and spaces below the electrode pads 96b of the semiconductor chip 96a can be reinforced with the insulating resin 96c.

In this way, by stacking the semiconductor chip 96a on the semiconductor chip 95a, it is possible to fix the semiconductor chips 95a, 96a while preventing the conductive wires 95d from contacting the rear surface of the semiconductor chip 96a, and while suppressing the height of the structure, it is possible to provide the semiconductor chip 94a between the carrier substrate 91 and the semiconductor chip 95a. This means that it is possible to stack the semiconductor chip 96a on the semiconductor chip 95a connected by wire bonding while suppressing the increases in the number of the manufacturing processes, and the number of stacked semiconductor chips 94a to 96a can be increased while making space savings.

It should be noted that the semiconductor device described above can be applied to electronic appliances such as a liquid crystal display, a mobile phone, a mobile information terminal, a video camera, a digital camera, a Mini Disk (MD) player or the like, and can be used to reduce the cost of an electronic appliance while making the electronic appliance smaller and lighter.

What is claimed is:

1. A semiconductor device, comprising:
a substrate provided with terminals for connecting conductive wires;
a first semiconductor chip mounted face-up on the substrate and electrically connected to the terminals provided on the substrate by the conductive wires; and
a second semiconductor chip having a projecting part formed on a rear surface thereof and attached onto the first semiconductor chip via the projecting part.

2. The semiconductor device according to claim 1, further comprising insulating resin that attaches the second semiconductor chip onto the first semiconductor chip via the projecting part.

3. The semiconductor device according to claim 2, wherein filler is mixed in with the insulating resin.

4. The semiconductor device according to claim 2, wherein the insulating resin fills at least part of a region of a stepped part in which the projecting part is provided.

5. A semiconductor device, comprising:
a substrate provided with terminals for connecting conductive wires;
a first semiconductor chip mounted face-up on the substrate;
first electrode pads provided on the first semiconductor chip;
first conductive wires electrically connecting the first electrode pads to the terminals provided on the substrate;
a second semiconductor chip having a projecting part formed on a rear surface thereof;
second electrode pads provided on the second semiconductor chip;
insulating resin enclosing the first conductive wires on the first semiconductor chip and attaching the second semiconductor chip onto the first semiconductor chip via the projecting part;
second conductive wires electrically connecting the second electrode pads and the terminals provided on the substrate; and
sealing resin sealing the first semiconductor chip to which the first conductive wires are connected and the second semiconductor chip to which the second conductive wires are connected.

6. A semiconductor device, comprising:
a substrate provided with terminals for connecting conductive wires;
a first semiconductor chip mounted face-up on the substrate;
first electrode pads provided on the first semiconductor chip;
first conductive wires electrically connecting the first electrode pads to the terminals provided on the substrate;
a second semiconductor chip having a projecting part formed on a rear surface thereof;
second electrode pads provided on the second semiconductor chip;
insulating resin provided between the first semiconductor chip and the second semiconductor chip so as to be present at least below the second electrode pads and attaching the second semiconductor chip onto the first semiconductor chip via the projecting part; and
second conductive wires electrically connecting the second electrode pads to the terminals provided on the substrate.

7. The semiconductor device according to claim 1, further comprising an insulating layer formed on an entire rear surface of the second semiconductor chip including the projecting part.

8. The semiconductor device according to claim 1, wherein at least part of a region of the projecting part is formed so as to widen towards a surface on which the projecting part is formed.

9. The semiconductor device according to claim 1, wherein a size of the second semiconductor chip is larger than a size of the first semiconductor chip.

10. A semiconductor device comprising:
a substrate provided with terminals for connecting conductive wires;
a first semiconductor chip mounted as a flip-chip on the substrate;
a second semiconductor chip mounted face-up on the first semiconductor chip via an adhesive layer;
first conductive wires electrically connecting the terminals provided on the substrate and the second semiconductor chip;
a third semiconductor chip having a projecting part formed on a rear surface thereof and attached onto the second semiconductor chip via the projecting part; and
second conductive wires electrically connecting the terminals provided on the substrate and the third semiconductor chip.

11. An electronic device comprising:
a substrate provided with terminals for connecting conductive wires;
a first electronic component mounted face-up on the substrate and electrically connected to the terminals provided on the substrate by the conductive wires; and
a second electronic component having a projecting part formed on a rear surface thereof and attached onto the first electronic component via the projecting part.

12. An electronic appliance comprising:
a substrate provided with terminals for connecting conductive wires;
a first semiconductor chip mounted face-up on the substrate and electrically connected to the terminals provided on the substrate by the conductive wires;
a second semiconductor chip having a projecting part formed on a rear surface thereof and attached onto the first semiconductor chip via the projecting part; and
an electronic component electrically connected to the first semiconductor chip and the second semiconductor chip via the substrate.

13. A method of manufacturing a semiconductor device, comprising:
mounting a first semiconductor chip on a substrate provided with terminals for connecting conductive wires;
connecting the first semiconductor chip mounted on the substrate and the terminals provided on the substrate with conductive wires; and
attaching a second semiconductor chip, having a projecting part formed on a rear surface thereof, onto the first semiconductor chip.

14. A method of manufacturing a semiconductor device, comprising:
mounting a first semiconductor chip on a substrate provided with terminals for connecting conductive wires;
connecting a first semiconductor chip mounted on the substrate and the terminals provided on the substrate with conductive wires;
disposing insulating resin on the first semiconductor chip; and
attaching a second semiconductor chip onto the first semiconductor chip by pressing a projecting part formed on a rear surface of the second semiconductor chip onto the insulating resin.

15. The method of manufacturing a semiconductor chip according to claim 13, further comprising:
half cutting a rear surface of a wafer, a surface of which has been divided by scribe lines, to form trenches that are disposed opposite the scribe lines; and
cutting the trenches along the scribe lines to form the second semiconductor chip that respectively has projecting parts formed on the rear surface thereof.

16. The method of manufacturing a semiconductor device according to claim 15, wherein the rear surface is half cut by one of dicing with a blade with a rounded tip, isotropic etching, and laser machining.

17. The method of manufacturing a semiconductor device according to claim 15, further comprising forming an insulating film on a rear surface of the wafer in which the trenches have been formed.

18. The semiconductor device according to claim 3, wherein the insulating resin fills at least part of a region of a stepped part in which the projecting part is provided.

19. The semiconductor device according to claim 2, further comprising an insulating layer formed on an entire rear surface of the second semiconductor chip including the projecting part.

20. The method of manufacturing a semiconductor chip according to claim 14, further comprising:
half cutting a rear surface of a wafer, a surface of which has been divided by scribe lines, to form trenches that are disposed opposite the scribe lines; and
cutting the trenches along the scribe lines to form the second semiconductor chip that respectively has projecting parts formed on the rear surface thereof.
